(19) United States
(12) Patent Application Publication
(10) Pub. No.: US 2011/0278697 A1
(43) Pub. Date: Nov. 17, 2011

(54) METAL-INSULATOR-METAL CAPACITOR AND METHOD FOR FABRICATING METAL-INSULATOR-METAL CAPACITOR STRUCTURES

(75) Inventors: Poh Cheng Tan, Singapore (SG); Ai Ling Catherine Ng, Singapore (SG)

(73) Assignee: SYSTEMS ON SILICON MANUFACTURING CO. PTE. LTD., Singapore (SG)

(21) Appl. No.: 12/781,528

(22) Filed: May 17, 2010

(51) Int. Cl. H01L 29/92; H01L 21/02

(52) U.S. Cl. 257/532; 438/393; 257/E29.342; 257/E21.008

(57) ABSTRACT

A Metal-Insulator-Metal Capacitor and Method for Fabricating Metal-Insulator-Metal Capacitor Structures. The MIM (Metal insulator Metal) capacitor structure comprising a Capacitor Top Metal (CTM); a dielectric; and a Capacitor Bottom Metal (CBM); said CTM comprising an etch stop portion; a conductivity portion having a lower resistivity compared to the etch stop portion; and an interface portion of a different material from the conductivity portion; wherein the conductivity portion is sandwiched between the etch stop portion and the interface portion; and the interface portion interfaces the CTM with the dielectric.

### TECHNICAL FIELD

The present invention relates to a capacitor; more specifically, to a Metal-Insulator-Metal (MIM) capacitor structure and method for fabricating MIM capacitor structures.

### BACKGROUND

MIM capacitors are widely used in RF integrated circuits as they generally induce lower parasitic effects when compared with other types of capacitors. Typically, MIM capacitors are formed by two parallel metal plates, separated by a thin dielectric. In the MIM capacitor, one of the metal plates is fabricated from a standard metal layer while the other metal plate is a special MIM metal layer.

FIG. 1 shows a MIM capacitor structure of the prior art. The MIM structure 100 comprises a capacitor bottom metal (CBM) 102, a dielectric 104 and a capacitor top metal (CTM) 106. The CBM 102 is made of a layer of AlCu (Aluminium Copper) 108 sandwiched between two layers of TiN (Titanium Nitride) or Ti-rich TiN 110a and 110b. The dielectric 104 is an oxide layer 112. The CTM 106 is a layer of TiN 114. The CBM 102 and CTM 106 are biased respectively through Vias 116 and 118. In this particular MIM structure 100, the CTM 106 comprising of a layer of TiN 114 is however, relatively more resistive compared with e.g. a layer of AlCu, and is therefore not ideal for use in high frequency devices due to a lower Q-factor attributed to higher series resistance in the CTM 106.

FIG. 2 shows another MIM capacitor structure 200 of the prior art. This structure 200 is similar to the structure 100 shown in FIG. 1 in that the CBM 202 is made of a layer of AlCu 208 sandwiched between two layers of TiN 210a and 210b, and the dielectric 204 is an oxide layer 212. However, instead of a layer of TiN as the CTM, the CTM 206 comprises a layer of AlCu 214 and a layer of TiN 216, with the AlCu 214 layer in contact with the dielectric layer 204. The AlCu 214 layer in the CTM provides reduced resistivity in contrast with a pure TiN CTM as illustrated in the MIM capacitor structure 100 of FIG. 1. However, the “matching” performance of the MIM capacitor structure 200 is poor and not suited for high precision analogue circuits. The capacitance of the MIM capacitor structure 200 produced cannot be identically reproduced in pairs of 2 or more that are identically drawn within a local vicinity on a wafer. Many analogue and high voltage electronic circuits' functionalities and their yields rely highly on the matching properties of both active and passive devices like transistors, capacitors, and resistors. As such, the capacitor structure 200 is not suited in high precision analogue circuit designs e.g. in analogy-to-digital converters, due to the higher mismatch.

Therefore, there exists a need to provide a MIM capacitor and method for fabricating MIM capacitors to address one or more of the problems mentioned above.

### SUMMARY

In accordance with a first aspect of the present invention, there is provided an MIM (Metal insulator Metal) capacitor structure comprising: a Capacitor Top Metal (CTM); a dielectric; and a Capacitor Bottom Metal (CBM); said CTM comprising an etch stop portion; a conductivity portion having a lower resistivity compared to the etch stop portion; and an interface portion of a different material from the conductivity portion; wherein the conductivity portion is sandwiched between the etch stop portion and the interface portion; and the interface portion interfaces the CTM with the dielectric.

The interface portion may provide a diffusion barrier.

The interface portion may provide increased breakdown voltage of the capacitor structure.

The etch stop portion may be a layer of Titanium rich Titanium Nitride (Ti-Rich TiN).

The Ti-Rich TiN may comprise a sub-layer of Titanium (Ti) and a sub-layer of Titanium Nitride (TiN).

The conductivity portion may be a layer of Aluminum Copper (AlCu).

The interface portion may comprise a layer comprising Titanium rich Titanium Nitride (Ti Rich TiN).

The interface portion may comprise a layer comprising Non-Ti-Rich TiN.

The layer of Non-Ti-Rich TiN may comprise only TiN.

The dielectric may be an oxide layer.

In accordance with a second aspect of the present invention, there is provided a method for fabricating an MIM (Metal insulator Metal) capacitor structure comprising the steps of providing a Capacitor Top Metal (CTM); providing a dielectric; and providing a Capacitor Bottom Metal (CBM); wherein providing the CTM comprises providing an etch stop portion; providing a conductivity portion having a lower resistivity compared to the etch stop portion; and providing an interface portion of a different material from the conductivity portion; such that the conductivity portion is sandwiched between the etch stop portion and the interface portion; and the interface portion interfaces the CTM with the dielectric.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1 shows a MIM capacitor structure of the prior art.

FIG. 2 shows another MIM capacitor structure of the prior art.

FIG. 3 shows an example embodiment of a MIM capacitor structure of the present invention.

FIG. 4a shows an example capacitor structure of the present invention.

FIG. 4b shows another example capacitor structure of the present invention.

FIG. 5 is a table summarising the performance of the example embodiment of the present invention when compared with the capacitor structures of the prior art.

FIG. 6 shows a chart which plots the CTM resistance for each type of capacitor structure.

FIG. 7 shows a chart which illustrates the matching performance for each type of capacitor structure.

FIG. 8 shows a chart which plots the capacitance for each of the capacitor structures across a range of biasing voltages.

FIG. 9 shows a chart which plots the leakage current for each of the capacitor structures across a range of biasing voltages.

FIG. 10 shows a flow chart illustrating a method for fabricating an MIM (Metal insulator Metal) capacitor structure.

### DETAILED DESCRIPTION OF ILLUSTRATIVE EMBODIMENTS

The embodiments of the present invention seek to provide a MIM capacitor structure, the MIM capacitor structure being suitable for use in high frequency integrated circuits, and in precision analogue design requiring low capacitor mismatch performance. In particular, the embodiments of the present invention provide MIM capacitor structures which have lower CTM electrical resistance and more consistent reproducibility as compared with the MIM capacitor structures of the prior art.

It will be appreciated that the thicknesses of the various layers in the example embodiments are for illustrative purposes only and that they may have alternative dimensions or scaled accordingly to cater to alternative processing techniques or the use of alternative materials.

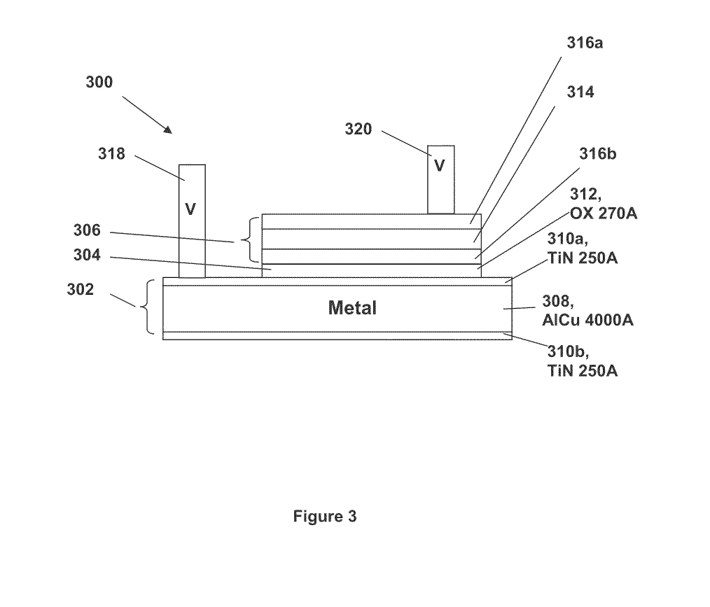

FIG. 3 shows an example embodiment of a MIM capacitor structure 300 of the present invention. The MIM capacitor structure 300 comprises a capacitor bottom metal (CBM) 302, a dielectric 304 and a capacitor top metal (CTM) 306. The CBM 302 comprises a layer of AlCu 308 sandwiched between two layers of TiN 310a and 310b. The dielectric 304 comprises e,g, an oxide. It will be appreciated that the oxide layer 312 may alternatively be a layer of nitride or a combination of oxide and nitride using LPCVD (Low Pressure Chemical Vapour deposition) or PECVD (Plasma-Enhanced Chemical Vapour deposition) of varying k value. The CTM 306 comprises an etch stop portion 316a, a conductivity portion 314 and an interface portion 316b. In example embodiments, the etch stop portion 316a, conductivity portion 314 and interface portion 316b may be a layer of TiN 700A, AlCu 1200A and TiN 500A respectively. The conductivity portion 314 is sandwiched between the etch stop portion 316a and interface portion 316b, with the interface portion 316b interfacing the CTM 306 with the dielectric 304. The CBM 302 and CTM 306 are biased respectively through vias 318 and 120.

The interface portion 316b is made of a material e.g. TiN which can provide electrical conductivity while maintaining low e.g. copper diffusivity. In this regard, the interface portion 316b, can therefore serve as a diffusion barrier to prevent e.g. copper in the conductivity layer 314 from diffusing to the surrounding materials including the oxide dielectric 312.

The etch stop portion 316a of e.g. a layer of TiN provide a layer of protection to the CTM 306. The hard, corrosion resistive properties of e.g. TiN provide protection against etching/corrosive steps subsequent to the fabrication of the CTM 306. In this regard, the etch stop portion layer 316a can provide protection to the softer conductivity portion 314 of e.g. AlCu.

Additionally, the etch stop portion 316a provides electrical conductivity to allow it to serve as a conductive interface for the CTM 306 to the respective Vias 318 and 320.

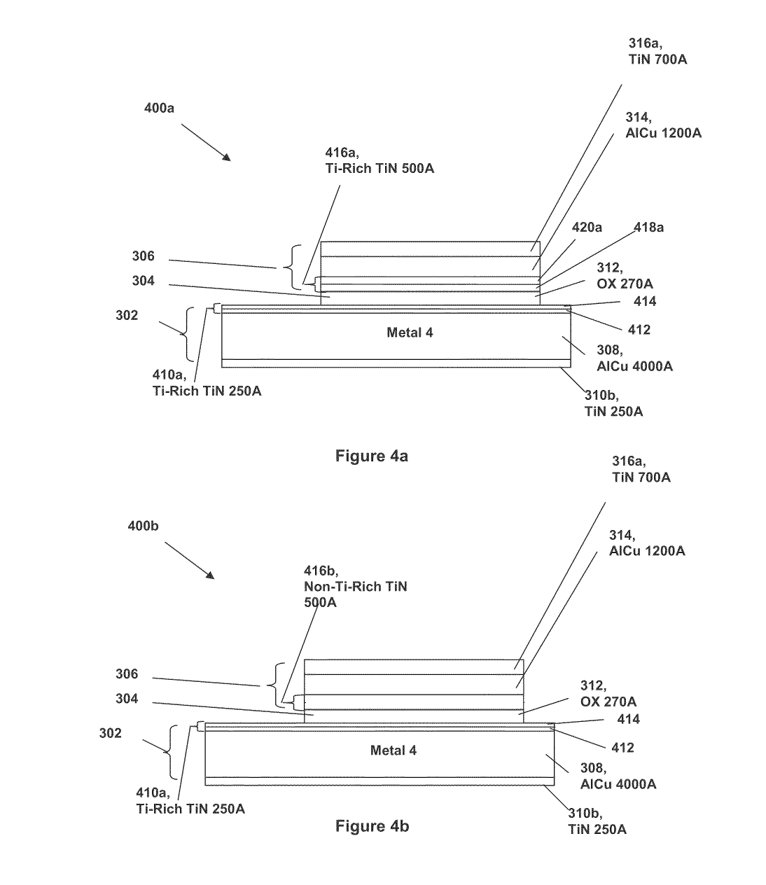

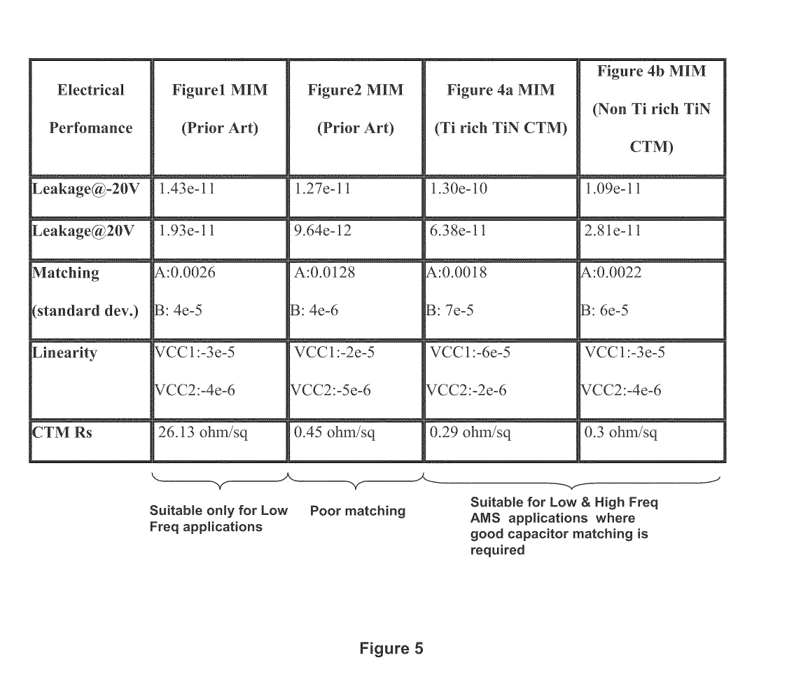

It will be appreciated by a person skilled in the art that while the example embodiments describe the use of TiN, AlCu, and TiN for the etch stop 316a, conductivity 314 and interface 316b layers or portions of the CTM 306 respectively, other materials may be used instead. Similarly, while dimensions e.g. thickness of each layer are indicated in the FIGS. 3, 4a and 4b for the example embodiments, it will be appreciated that the dimensions are merely illustrative and other appropriate dimensions for similar or different materials maybe applicable.

FIG. 4a shows an example embodiment 400a of the present invention, illustrating the e.g. TiN layers 410a and 416a in greater detail. In the example embodiment of the capacitor structure 400a of the present invention, the TiN layer 410a is a Ti-rich layer which comprises two sub layers, namely a sub-layer of Ti 412 and a sub-layer of TiN 414. The TiN sub-layer 414 is sandwiched between the dielectric 312 and the Ti sub-layer 412. The TiN layer 416a is also a Ti-rich layer which comprises a sub-layer of Ti 418a sandwiched between the dielectric and a sub-layer of TiN 420a. As such, the dielectric 304 is in contact with the TiN sub-layer 412 of the CBM 302 and the Ti sub-layer 418a of the CTM 306.

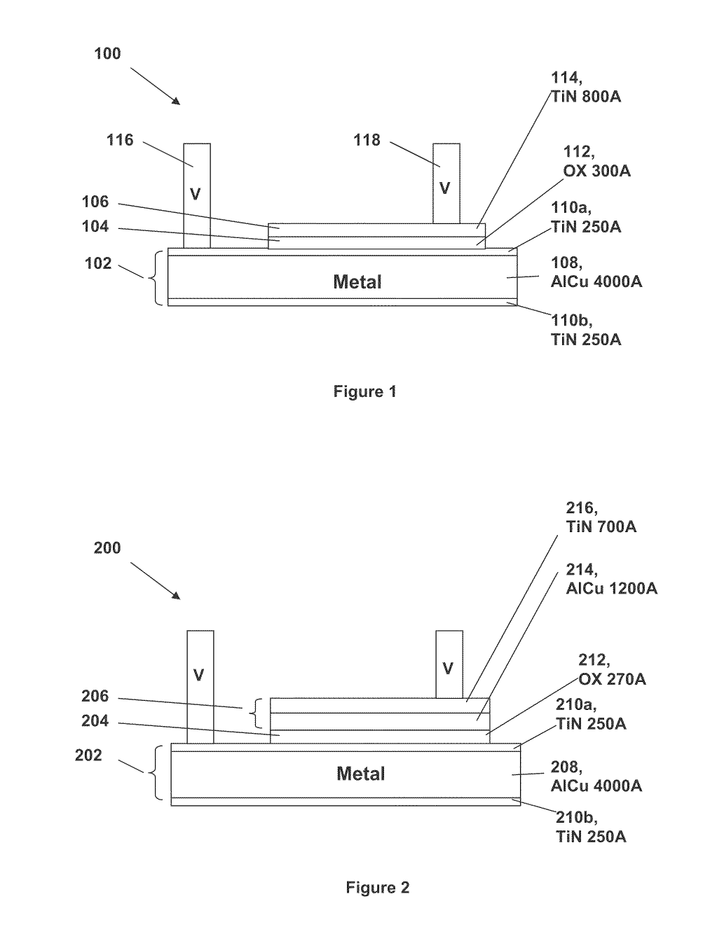

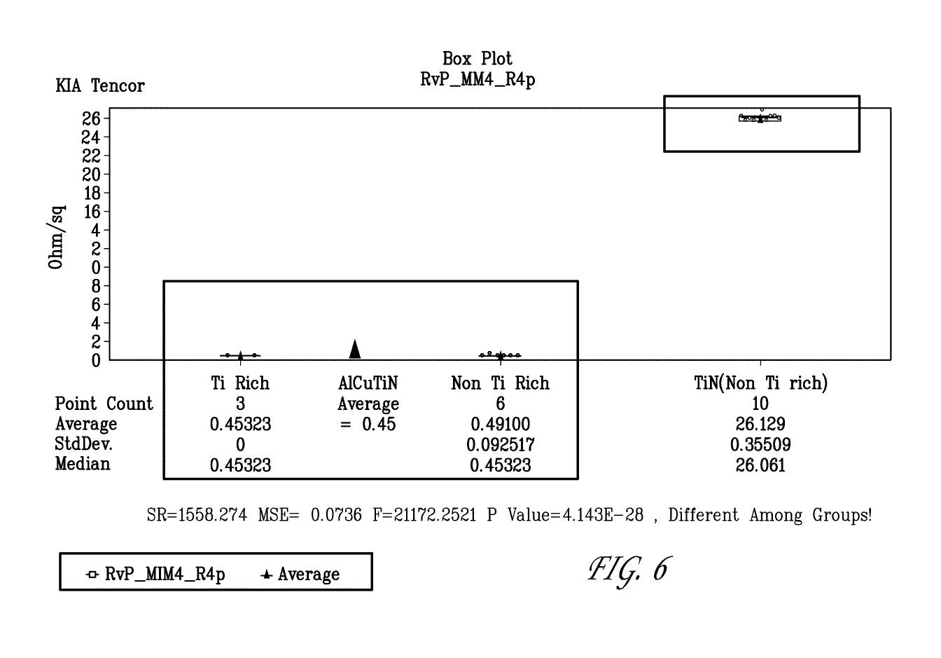

FIG. 5 is a table summarising the performance of the example embodiment of the present invention when compared with the capacitor structures of the prior art. The example embodiment 400a illustrated in FIG. 4a shows improved performance when compared with the two capacitor structures 100 and 200 illustrated in FIGS. 1 and 2. Most notably, the example embodiment 400a illustrated in FIG. 4a shows reduced CTM resistance when compared with the capacitor structure 100 of FIG. 1.

FIG. 6 shows a chart which plots the CTM resistance for each type of capacitor structure. As illustrated in FIG. 6, the capacitor structure 100 of FIG. 1 shows an average CTM resistance which is almost 60 times greater than the capacitor structure 400a of FIG. 4a (0.29 vs 26 ohms/sq).

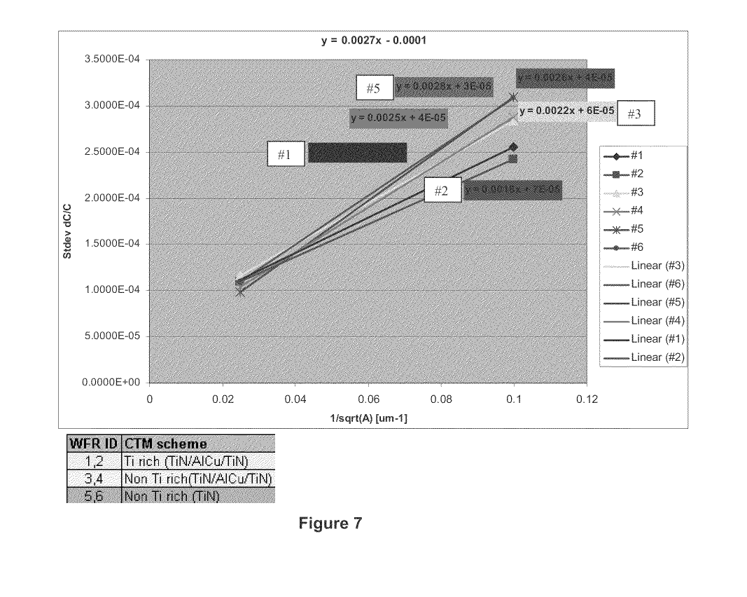

FIG. 7 shows a chart which illustrates the matching performance for the different capacitor structures. A lower standard deviation is observed for the embodiment 400a of FIG. 4 (wafers #1, #2), when compared with the capacitor structure 100 of FIG. 1 (wafers #5, #6).

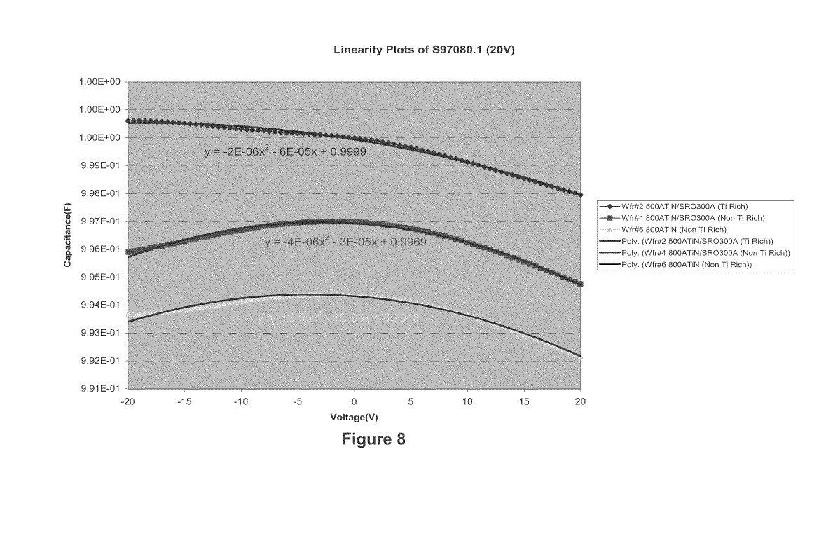

For completeness, the linearity performance of the capacitor structures 100 (FIGS. 1) and 400a (FIG. 4a) are also included in FIG. 5. FIG. 8 shows the chart which plots the capacitance for the different capacitor structures across a range of biasing voltages. A more linear performance is observed across the range of biasing voltages for the embodiment 400a of FIG. 4 (wafer #2), when compared with the capacitor structure 100 of FIG. 1 (wafer #6).

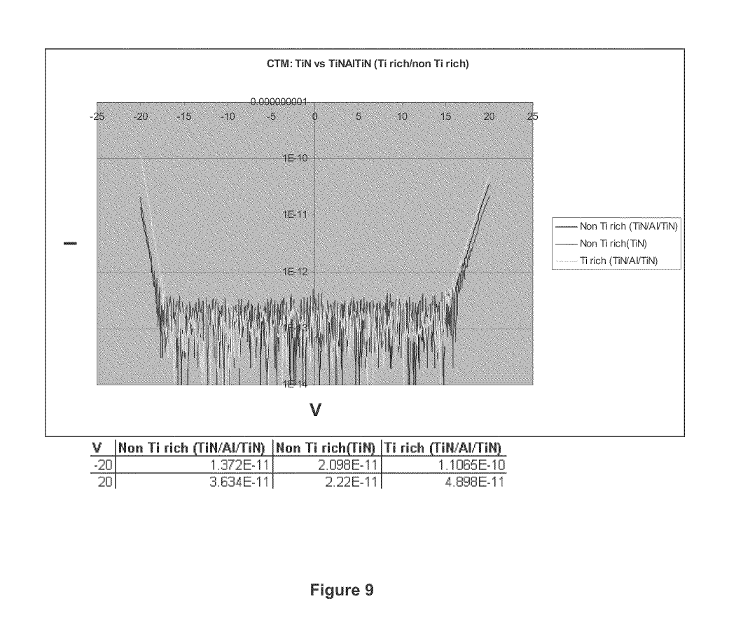

For the capacitor structure 400a, as illustrated in detail in FIG. 9, when the CTM is biased at −20V to the CBM, leakage is however greater than the capacitor structure 100 of FIG. 1, indicating comparatively lower breakdown voltage. The capacitor structure 400a is nonetheless, useful for a smaller operating voltage range of e.g. −15V to 15V.

Also, the inventors have recognised that the leakage at −20V for the capacitor structure 400a of FIG. 4a may be reduced in a structure where instead of a Ti-Rich layer 416a with the Ti sub-layer 418a (FIG. 4a) in contact with the dielectric, a Non-Ti-Rich TiN layer is provided. The Non-Ti-Rich TiN layer 416b (FIG. 4b) comprises a TiN layer which is in contact with the dielectric rather than the Ti layer 418a.

FIG. 4b shows such an example embodiment 400b of the present invention. The capacitor structure 400b of FIG. 4b is identical with the capacitor structure 400a of FIG. 4a except for the Non-Ti-Rich TiN layer 416b in place of the Ti-Rich TiN layer 416a in the capacitor structure 400a. The Non-Ti-Rich TiN interface layer 416b at the CTM 306 is symmetrical with the Ti-Rich TiN interface layer 410a at the CBM 302, such that at both sides of the dielectric, it is the TiN sub-layers 414, and TiN layer 416b which are in contact with the dielectric. The TiN layer 416b is also in contact with the conductivity layer 314, while the Ti sub-layers 412, is in contact with conductivity layer 308.

As illustrated in FIG. 5, the CTM resistivity, matching and linearity performance of the capacitor structure 400b is comparable to that of capacitor structure 400a (FIGS. 4b and 4a respectively). Additionally, the capacitor structure 400b further provides better leakage performance such that when the CTM is biased at −20V with respect to the CBM, its leakage performance is similar to that of the capacitor structure 100 of FIG. 1.

The embodiments of the present invention are capable of improving the electrical performances of MIM capacitors. In particular, they can improve the matching performance and reduce the CTM resistances of the MIM capacitors. Further, the inclusion of TiN (Non-Ti-Rich) on the CTM stack at the interface between the CTM and the dielectric can maintain the capacitor electrical performance without degradation in the leakage performance. The embodiments of the present invention are thus especially useful in RF/MM devices, where reduced CTM resistances are critical to their functionality.

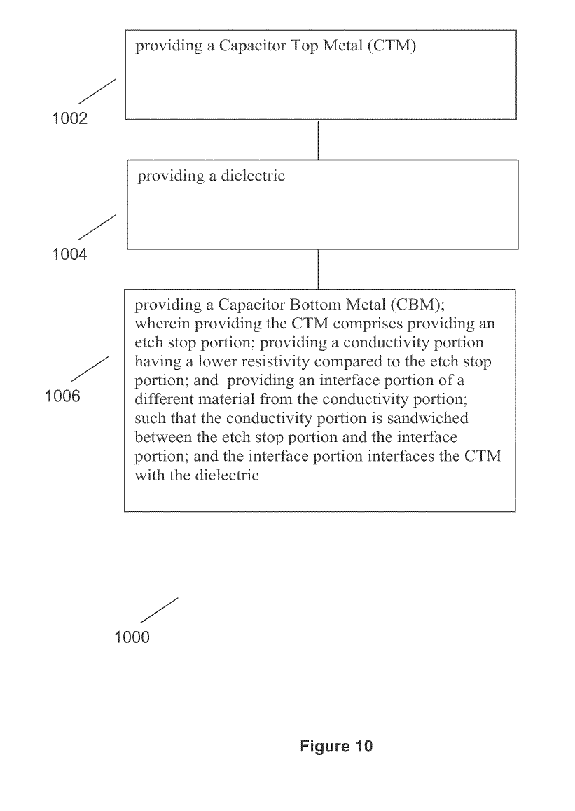

FIG. 10 is a flowchart 1000 illustrating a method for fabricating an MIM (Metal insulator Metal) capacitor structure. At step 1002, a Capacitor Top Metal (CTM) is provided. At step 1004, a dielectric is provided. At step 1006, a Capacitor Bottom Metal (CBM) is provided, wherein providing the CTM comprises providing an etch stop portion; providing a conductivity portion having a lower resistivity compared to the etch stop portion; and providing an interface portion of a different material from the conductivity portion; such that the conductivity portion is sandwiched between the etch stop portion and the interface portion; and the interface portion interfaces the CTM with the dielectric. Suitable formation techniques are understood in the art and are therefore not described in detail herein.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

What is claimed:

1. An MIM (Metal insulator Metal) capacitor structure comprising
a Capacitor Top Metal (CTM);
a dielectric; and
a Capacitor Bottom Metal (CBM);
said CTM comprising
an etch stop portion;
a conductivity portion having a lower resistivity compared to the etch stop portion;
and an interface portion of a different material from the conductivity portion;
wherein the conductivity portion is sandwiched between the etch stop portion and the interface portion; and the interface portion interfaces the CTM with the dielectric.

2. The capacitor structure as claimed in claim 1, wherein the interface portion provides a diffusion barrier.

3. The capacitor structure as claimed in claim 1, wherein the interface portion provides increased breakdown voltage of the capacitor structure.

4. The capacitor structure as claimed in claims 1 wherein the etch stop portion is a layer of Titanium rich Titanium Nitride (Ti-Rich TiN).

5. The capacitor structure as claimed in claim 4, wherein the Ti-Rich TiN comprises a sub-layer of Titanium (Ti) and a sub-layer of Titanium Nitride (TiN).

6. The capacitor structure as claimed in claim 1, wherein the conductivity portion is a layer of Aluminum Copper (AlCu).

7. The capacitor structure as claimed in claim 1, wherein the interface portion comprises a layer comprising Titanium rich Titanium Nitride (Ti Rich TiN).

8. The capacitor structure as claimed in claim 1, wherein the interface portion comprises a layer comprising Non-Ti-Rich TiN.

9. The capacitor structure as claimed in claim 8, wherein the layer of Non-Ti-Rich TiN comprises only TiN.

10. The capacitor structure as claimed in claim 1, wherein the dielectric is an oxide layer.

11. A method for fabricating an MIM (Metal insulator Metal) capacitor structure comprising the steps of
providing a Capacitor Top Metal (CTM);
providing a dielectric; and
providing a Capacitor Bottom Metal (CBM);
wherein providing the CTM comprises
providing an etch stop portion;
providing a conductivity portion having a lower resistivity compared to the etch stop portion; and
providing an interface portion of a different material from the conductivity portion;
such that the conductivity portion is sandwiched between the etch stop portion and the interface portion; and the interface portion interfaces the CTM with the dielectric.
